(19) United States
(12) Patent Application Publication
(10) Pub. No.: US 2008/0142874 A1
(43) Pub. Date: Jun. 19, 2008

(54) INTEGRATED CIRCUIT SYSTEM WITH IMPLANT OXIDE

(75) Inventors: Shenqing Fang, Fremont, CA (US); Rinji Sugino, San Jose, CA (US); Jayendra Bhakta, Sunnyvale, CA (US); Takashi Orimoto, Sunnyvale, CA (US); Hiroyuki Nansei, Fukushima-ken (JP); Yukio Hayakawa, Cupertino, CA (US); Hidehiko Shiraiwa, San Jose, CA (US); Takayuki Maruyama, Fukushima-ken (JP); Kuo-Tung Chang, Saratoga, CA (US); YouSeok Suh, Cupertino, CA (US); Amol Ramesh Joshi, Sunnyvale, CA (US); Harpreet Sachar, Milpitas, CA (US); Simon Siu-Sing Chan, Saratoga, CA (US)

Correspondence Address: FARJAMI & FARJAMI LLP, 26522 LA ALAMEDA AVENUE, SUITE 360, MISSION VIEJO, CA, 92691, US

(73) Assignees: Spansion LLC, Sunnyvale, CA (US); Advanced Micro Devices, Inc., Sunnyvale, CA (US)

(21) Appl. No.: 11/611,860

(22) Filed: Dec. 16, 2006

(51) Int. Cl. H01L 29/792; H01L 21/3205

(52) U.S. Cl. 257/324; 438/596; 257/E21.294; 257/E29.309

(57) ABSTRACT

A method for forming an integrated circuit system is provided including forming a substrate; forming a stack over the substrate, the stack having a sidewall and formed from a charge trap layer and a semi-conducting layer; and slot plane antenna oxidizing the stack for forming a protection enclosure having a protection layer along the sidewall.

### TECHNICAL FIELD

The present invention relates generally to integrated circuit system and more particularly to non-volatile memory system.

### BACKGROUND ART

Modern electronics, such as smart phones, personal digital assistants, location based services devices, digital cameras, music players, servers, and storage arrays, are packing more integrated circuits into an ever shrinking physical space with expectations for decreasing cost. One cornerstone for electronics to continue proliferation into everyday life is the non-volatile storage of information such as cellular phone numbers, digital pictures, or music files. Numerous technologies have been developed to meet these requirements.

Various types of non-volatile memories have been developed including electrically erasable programmable read only memory (EEPROM) and electrically programmable read only memory (EPROM). Each type of memory had advantages and disadvantages. EEPROM can be easily erased without extra exterior equipment but with reduced data storage density, lower speed, and higher cost. EPROM, in contrast, is less expensive and has greater density but lacks erasability.

A newer type of memory called “Flash” EEPROM, or Flash memory, has become popular because it combines the advantages of the high density and low cost of EPROM with the electrical erasability of EEPROM. Flash memory can be rewritten and can hold its contents without power. Contemporary Flash memories are designed in a floating gate or a charge trapping architecture. Each architecture has its advantages and disadvantages.

The floating gate architecture offers implementation simplicity. This architecture embeds a gate structure, called a floating gate, inside a conventional metal oxide semiconductor (MOS) transistor gate stack. Electrons can be injected and stored in the floating gate as well as erased using an electrical field or ultraviolet light. The stored information may be interpreted as a value “0” or “1” from the threshold voltage value depending upon charge stored in the floating gate. As the demand for Flash memories increases, the Flash memories must scale with new semiconductor processes. However, new semiconductor process causes a reduction of key feature sizes in Flash memories of the floating gate architecture, which results in undesired disturb by neighboring cells as well as degradation of data retention and endurance.

The charge trapping architecture offers improved scalability to new semiconductor processes compared to the floating gate architecture. One implementation of the charge trapping architecture is a silicon-oxide-nitride-oxide semiconductor (SONOS) where the charge is trapped in the nitride layer. Leakage and charge-trapping efficiency are two major parameters considered in device performance evaluation. Charge-trapping efficiency determines if the memory devices can keep enough charges in the storage nodes after program/erase operation and is reflected in retention characteristics. It is especially critical when the leakage behavior of storage devices is inevitable.

SONOS Flash memories suffer from poor programming performance. Silicon content in the nitride layer improves the programming and erasing performances but offers poor data retention. Although silicon content plays an important role in charge-trapping efficiency, it does not have same constructive effect on leakage characteristics. The interface between the charge trapping layer with both the top blocking oxide layer and the bottom tunneling oxide layer present both scaling and functional problems despite the silicon content as well as add cost to the manufacturing process.

For example, implant oxide is used after transistor gate definition to prevent implant damage to the gate sidewall. Typically, thermal oxidation or chemical vapor deposition are used to form the implant oxide along the gate sidewalls. Both approaches have drawbacks affecting performance, yield, reliability, and cost.

Thermal implant oxidation causes encroachment in the memory stack that degrades both erase and program performance. The performance degradation may be attributed to the degradation of the tunnel oxide and the oxide-nitride-oxide structures of the memory stack. The encroachment may protrude the nitride layer causing charge retention and other reliability problems. The performance degradation worsens as memory cell sizes decreases limiting scalability.

Chemical vapor deposition (CVD) implant oxidation does not cause encroachment as much as thermal oxidation but has other drawbacks. The CVD process forms an interface between the oxide layers and the charge trapping layer, e.g. the nitride layer that is lower in quality than that formed by thermal oxidation. The CVD process forms sharp gate edges degrading the tunnel oxide during erase and programming operations.

Thus, a need still remains for an integrated circuit system providing low cost manufacturing, improved yields, improved programming performance, and improved data retention of memory in a system. In view of the ever-increasing need to save costs and improve efficiencies, it is more and more critical that answers be found to these problems.

Solutions to these problems have been long sought but prior developments have not taught or suggested any solutions and, thus, solutions to these problems have long eluded those skilled in the art.

### DISCLOSURE OF THE INVENTION

The present invention provides an integrated circuit system including forming a substrate; forming a stack over the substrate, the stack having a sidewall and formed from a charge trap layer and a semi-conducting layer; and slot plane antenna oxidizing the stack for forming a protection enclosure having a protection layer along the sidewall.

Certain embodiments of the invention have other aspects in addition to or in place of those mentioned or obvious from the above. The aspects will become apparent to those skilled in the art from a reading of the following detailed description when taken with reference to the accompanying drawings.

### BRIEF DESCRIPTION OF THE DRAWINGS

FIGS. 1A, 1B, and 1C are schematic views of examples of electronics systems in which various aspects of the present invention may be implemented;

FIG. 2 is a plan view of an integrated circuit system in an embodiment of the present invention;

FIG. 3 is a cross-sectional view of a memory system along a line segment 3-3 of FIG. 2 in a mask phase;

FIG. 4 is the structure of FIG. 3 in a first etch phase;

FIG. 5 is the structure of FIG. 4 in a second etch phase;

FIG. 6 is the structure of FIG. 5 in a third etch phase;

FIG. 7 is the structure of FIG. 6 in a protection phase;

FIG. 8 is a more detailed view of the structure of FIG. 7; and

FIG. 9 is a flow chart of an integrated circuit system for manufacture of the integrated circuit system in an embodiment of the present invention.

### BEST MODE FOR CARRYING OUT THE INVENTION

In the following description, numerous specific details are given to provide a thorough understanding of the invention. However, it will be apparent that the invention may be practiced without these specific details. In order to avoid obscuring the present invention, some well-known system configurations, and process steps are not disclosed in detail. Likewise, the drawings showing embodiments of the apparatus are semi-diagrammatic and not to scale and, particularly, some of the dimensions are for the clarity of presentation and are shown greatly exaggerated in the figures. In addition, where multiple embodiments are disclosed and described having some features in common, for clarity and ease of illustration, description, and comprehension thereof, similar and like features one to another will ordinarily be described with like reference numerals.

The term “horizontal” as used herein is defined as a plane parallel to the conventional integrated circuit surface, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane. The term “on” means there is direct contact among elements.

The term “processing” as used herein includes deposition of material, patterning, exposure, development, etching, cleaning, molding, and/or removal of the material or as required in forming a described structure.

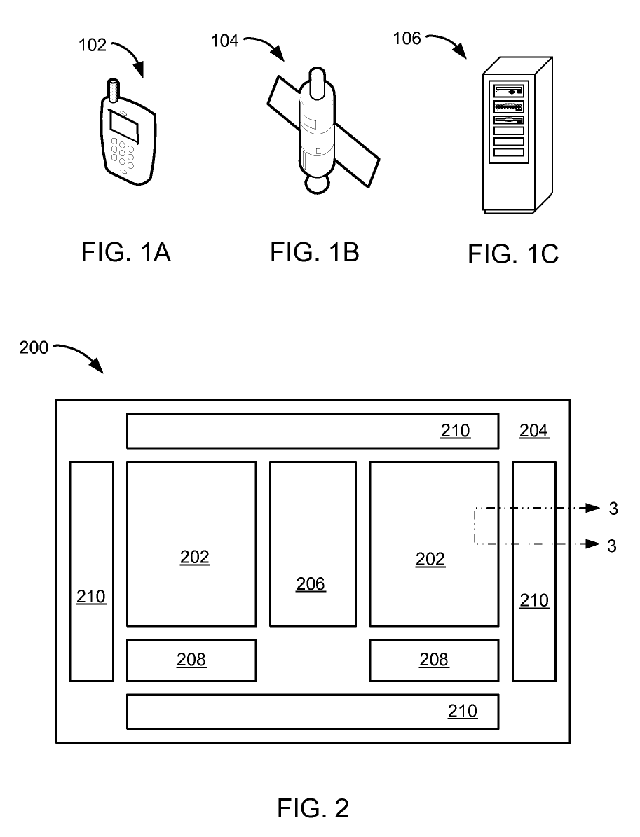

Referring now to FIGS. 1A, 1B, and 1C, therein are shown schematic views of examples of electronics systems in which various aspects of the present invention may be implemented. A smart phone 102, a satellite 104, and a compute system 106 are examples of the electronic systems using the present invention. The electronic systems may be any system that performs any function for the creation, transportation, storage, and consumption of information. For example, the smart phone 102 may create information by transmitting voice to the satellite 104. The satellite 104 is used to transport the information to the compute system 106. The compute system 106 may be used to store the information. The smart phone 102 may also consume information sent from the satellite 104.

The electronic systems, such as the smart phone 102, the satellite 104, and the compute system 106, include a one or more subsystem, such as a printed circuit board having the present invention or an electronic assembly having the present invention. The electronic system may also include a subsystem, such as an adapter card.

Referring now to FIG. 2, therein is shown a plan view of an integrated circuit system 200 in an embodiment of the present invention. The plan view depicts memory systems 202 in a semiconductor substrate 204, wherein the semiconductor substrate 204 has one or more high-density core regions and one or more low-density peripheral portions are formed.

High-density core regions typically include one or more of the memory systems 202. Low-density peripheral portions typically include input/output (I/O) circuitry and programming circuitry for individually and selectively addressing a location in each of the memory systems 202.

The programming circuitry is represented in part by and includes one or more x-decoders 206 and y-decoders 208, cooperating with I/O circuitry 210 for connecting the source, gate, and drain of selected addressed memory cells to predetermined voltages or impedances to effect designated operations on the memory cell, e.g. programming, reading, and erasing, and deriving necessary voltages to effect such operations. For illustrative purposes, the integrated circuit system 200 is shown as a memory device, although it is understood that the integrated circuit system 200 may other semiconductor devices having other functional blocks, such as a digital logic block, a processor, or other types of memories.

Referring now to FIG. 3, therein is a cross-sectional view of a memory system 300 along a line segment 3-3 of FIG. 2 in an embodiment of the present invention. The memory system 300 may represent the memory systems 202 of FIG. 2. The memory system 300 has a substrate 302, such as a semiconductor substrate. A first insulator layer 304, such as a bottom tunneling oxide layer, is formed over the substrate 302, such as a semiconductor substrate.

A charge trap layer 306, such as a silicon rich nitride layer (SRN or SiRN) or silicon nitride (Si_{X}N_{Y}), is formed over the first insulator layer 304. The silicon-rich nitride may be formed by a chemical vapor deposition process (CVD) using NH₃ and SiCl₂H₂ but not limited to the two chemicals. A ratio of the gases, such as NH₃:SiCl₂H₂, range from 1:40 to 1:1 can produce silicon-rich nitride with a ratio of Si to N higher than 0.75.

For illustrative purposes, the charge trap layer 306 is shown as a single layer, although it is understood that the charge trap layer 306 may have multiple layers, such as a nitride layer over a silicon rich nitride layer. Also for illustrative purposes, the charge trap layer 306 is shown as a single uniform layer, although it is understood that the charge trap layer 306 may include one or more layer having a concentration gradient, such as different gradient concentrations of silicon.

A second insulator layer 308, such as a top blocking layer oxide layer, is formed over the charge trap layer 306. A semi-conducting layer 310, such as a polysilicon layer, is formed over the second insulator layer 308. A third insulator layer 312, such as an oxide layer, is formed over the semi-conducting layer 310 and may function as a hard mask. The third insulator layer 312 may be formed by a number of different processes, such as chemical vapor deposition (CVD). An anti-reflective layer 314 is deposited by as chemical vapor deposition and patterned over the third insulator layer 312 by photolithography and dry etch.

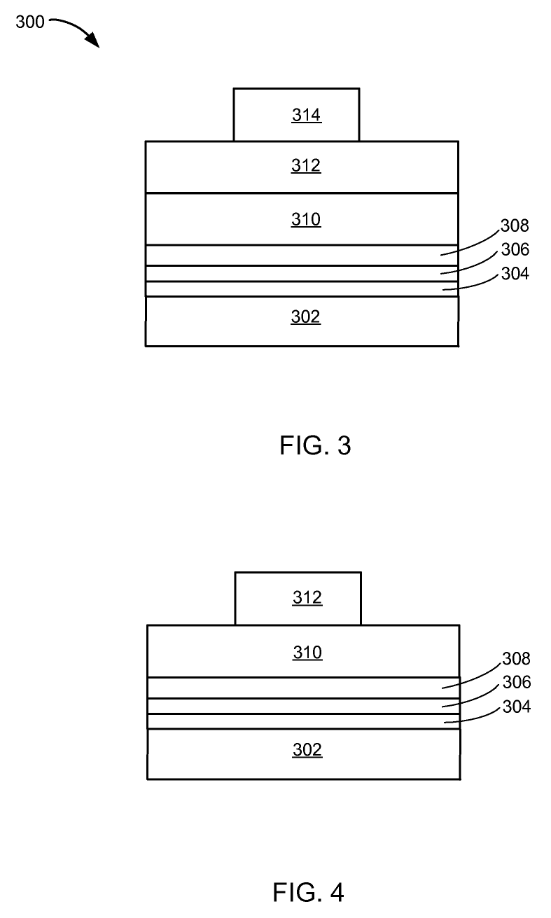

Referring now to FIG. 4, therein is the structure of FIG. 3 in a first etch phase. The structure of FIG. 3 undergoes an etching process, such as an anisotropic etch process. The third insulator layer 312 under the anti-reflective layer 314 of FIG. 3 is protected from the etching process. The etching process removes portions of the third insulator layer 312 not protected by the anti-reflective layer 314.

The anti-reflective layer 314 is removed leaving the third insulator layer 312 that has been patterned by the etching process. The anti-reflective layer 314 may be removed by a number of different processes, such as a separate plasma dry etching process. The substrate 302, the first insulator layer 304, the charge trap layer 306, and the second insulator layer 308 are not adversely affected by the etching process or the removal of the anti-reflective layer 314.

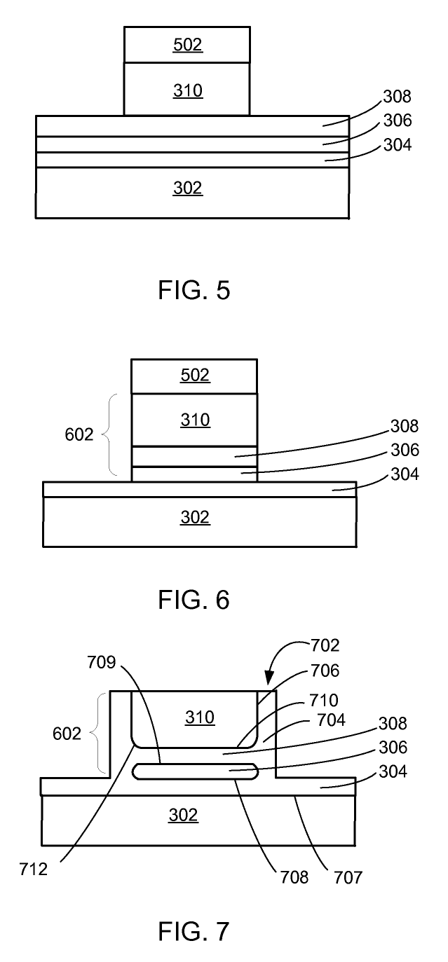

Referring now to FIG. 5, therein is shown the structure of FIG. 4 in a second etch phase. The structure of FIG. 4 undergoes an etching process, such as an anisotropic etch process. The etching process in FIG. 4 removes some portion of the third insulator layer 312 of FIG. 4 forming a thinned insulator 502. The semi-conducting layer 310 under that the thinned insulator 502 is protected from the etching process. The etching process removes portions of the semi-conducting layer 310 not under the thinned insulator 502. The etching process has a selectivity not to etch the second insulator layer 308. The substrate 302, the first insulator layer 304, and the charge trap layer 306 are not adversely affected by the etching process.

Referring now to FIG. 6, therein is shown the structure of FIG. 5 in a third etch phase. The structure of FIG. 5 undergoes an etching process, such as an anisotropic etch process. The second insulator layer 308 and the charge trap layer 306 under the thinned insulator 502 as well as the semi-conducting layer 310 are protected from the etching process. The etching process removes portions of the second insulator layer 308 and the charge trap layer 306 not under the thinned insulator 502 forming a stack 602, such as a gate stack.

The stack 602 includes the first insulator layer 304, the charge trap layer 306, the second insulator layer 308, and the semi-conducting layer 310. The etching process may be timed not to substantially etch the first insulator layer 304. The substrate 302 is not adversely affected by the etching process.

Referring now to FIG. 7, therein is shown the structure of FIG. 6 in a protection phase. The structure of FIG. 6 undergoes an implant oxidation utilizing a slot plane antenna (SPA) plasma technique forming a protection enclosure 702. The protection enclosure 702 includes the first insulator layer 304, the second insulator layer 308, and a protection layer 704, such as a layer comprised of oxide. The protection layer 704 is along sidewalls 706 of the stack 602 protecting the charge trap layer 306, the second insulator layer 308, and the semi-conducting layer 310.

The stack 602 has a number of interfaces. A first interface 707 is the interface formed by the first insulator layer 304 and the substrate 302. A second interface 708 is the interface formed by the first insulator layer 304 and the charge trap layer 306. A third interface 709 is the interface formed by the charge trap layer 306 and the second insulator layer 308. A fourth interface 710 is the interface formed by the second insulator layer 308 and the semi-conducting layer 310.

The charge trapping efficiency is determined by the silicon content in the charge trap layer 306. A conventional implant oxide is formed by thermal oxidation. Under a high temperature, oxygen diffuses through the second insulator layer 308 and the first insulator layer 304 to the first interface 707, the second interface 708, the third interface 709, and the fourth interface 710. The oxygen diffusion changes the chemical contents of the charge trap layer 306 near the first interface 707 and the third interface 709, degrading program and erase speed. The thermal oxidation makes the second insulator layer 308 and the first insulator layer 304 thicker gradually from the center to the gate edges, which is called encroachment. The encroachment degrades device reliability due to poor oxide quality at the first interface 707 and the fourth interface 710.

Another conventional implant oxide is formed by CVD. CVD oxide does not form a rounded corner 712 of the semi-conducting layer 310, such as the gate. Without the rounded corner 712, the local electrical field at the gate edges is higher during program and erase. The local high electrical field causes the gate corners to inject electron during erase, prohibiting the device threshold (Vt) to be further erased, and reduces the program-erase operation window. The local high electrical field degrades the ONO stack much faster at the edge, wherein the ONO stack includes the first insulator layer 304, the charge trap layer 306, and the second insulator layer 308.

The SPA technique produces high-density plasmas at low electron temperatures to enable damage-free processes at temperatures no higher than 600° C. Oxygen does not diffuse through the second insulator layer 308 and the first insulator layer 304 to the first interface 707, the second interface 708, the third interface 709, and the fourth interface 710 due to the low temperature. Thus, the oxidation process with SPA does not change the chemical content of the charge trap layer 306 and minimizes the encroachment. SPA oxidation forms the rounded corner 712. Therefore, the SPA implant oxide improves program and erase speed and device reliability.

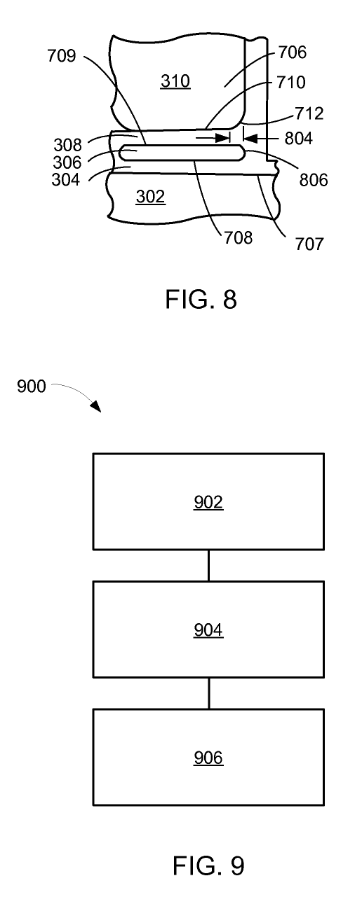

Referring now to FIG. 8, therein is shown a more detailed view of the structure of FIG. 7. The more detailed view depicts portions of the substrate 302, the first insulator layer 304, the charge trap layer 306, the second insulator layer 308, and the semi-conducting layer 310. The more detailed view also depicts the first interface 707, the second interface 708, the third interface 709, and the fourth interface 710.

The second interface 708 shows a controlled oxidation of the peripheral region of the charge trap layer 306 as characterized by a rounded end 806 at the periphery of the charge trap layer 306. The fourth interface 710 shows the rounded corner 712 of the semi-conducting layer 310 having a controlled oxidation of the peripheral region of the semi-conducting layer 310 at the fourth interface 710.

It has been discovered that the SPA oxidation controls oxidization the semi-conducting layer 310 and the charge trap layer 306. The SPA oxidation forms the rounded corner 802 of the semi-conducting layer 310 mitigating or eliminating electron injection from the semi-conducting layer 310 to the charge trap layer 306. The SPA oxidation also mitigates or eliminates encroachment for the life of the integrated circuit system 200 of FIG. 2. The SPA oxidation selectivity may be adjusted controlling the amount of a protrusion 804 of the charge trap layer 306.

Referring now to FIG. 9, therein is shown a flow chart of an integrated circuit system 900 for manufacture of the integrated circuit system 200 in an embodiment of the present invention. The system 900 includes forming a substrate in a block 902; forming a stack over the substrate, the stack having a sidewall and formed from a charge trap layer and a semi-conducting layer in a block 904; and slot plane antenna oxidizing the stack for forming a protection enclosure having a protection layer along the sidewall in a block 906.

Potential aspects of the invention that have been discovered is that the SPA oxidation provides improved interfaces within an integrated circuit, increased reliability, and improved erase and programming performance for a memory circuit.

Aspects of the embodiments include that the SPA oxidation may control the oxidization at the semi-conducting layer and the charge trap layer. The SPA oxidation selectivity may be adjusted controlling the amount of a protrusion of the charge trap layer.

Other aspects of the embodiments include that the SPA oxidation forms rounded corners of the semi-conducting layer at the interface facing the charge trap layer. The rounded corners mitigate or eliminate electron injection from the semi-conducting layer to the charge trap layer, which may reduce erase performance or modify the threshold voltage where the charge trap layer cannot be erased.

Other aspects of the embodiments include that the SPA oxidation also mitigates or eliminates encroachment of the semi-conducting layer forming protrusions of the charge trap layer. The encroachment may cause reliability problems. In addition, the protrusion of the charge trap layer may also cause reliability problems.

Other aspects of the embodiments include that the SPA oxidation is performed with a low temperature range, such as a range about 300° C. to 600° C., rounding the polysilicon layer to reduce or eliminate encroachment.

Other aspects of the embodiments include that the SPA oxidation grows the oxide for forming the protection layer, at the first interface, the second interface, the third interface, and the fourth interface improving the oxide quality over a deposition of oxide.

Other important aspects of the embodiments are that they valuably support and service the historical trend of reducing costs, simplifying systems, and increasing performance.

These and other valuable aspects of the embodiments consequently further the state of the technology to at least the next level.

Thus, it has been discovered that the integrated circuit system method and apparatus of the present invention furnish important and heretofore unknown and unavailable solutions, capabilities, and functional aspects for integrated circuit systems. The resulting processes and configurations are straightforward, cost-effective, uncomplicated, highly versatile, accurate, sensitive, and effective, and can be implemented by adapting known components for ready, efficient, and economical manufacturing, application, and utilization.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations, which fall within the scope of the included claims. All matters hithertofore set forth herein or shown in the accompanying drawings are to be interpreted in an illustrative and non-limiting sense.

What is claimed is:

1. A method for forming an integrated circuit system comprising:
forming a substrate;
forming a stack over the substrate, the stack having a sidewall and formed from a charge trap layer and a semi-conducting layer; and
slot plane antenna oxidizing the stack for forming a protection enclosure having a protection layer along the sidewall.

2. The method as claimed in claim 1 wherein the slot plane antenna oxidizing includes controlling a protrusion of the charge trap layer by adjusting the oxidation selectivity.

3. The method as claimed in claim 1 wherein the slot plane antenna oxidizing includes forming a rounded corner of the semi-conducting layer.

4. The method as claimed in claim 1 wherein the slot plane antenna oxidizing includes forming a rounded end of the charge trap layer.

5. The method as claimed in claim 1 further comprising forming an electronic system or a subsystem with the integrated circuit system.

6. A method for forming an integrated circuit system comprising:
forming a substrate;
forming a gate stack over the substrate, the gate stack having a sidewall and formed from a bottom tunneling oxide layer, a charge trap layer having silicon, a top blocking oxide layer, and a polysilicon layer; and
slot plane antenna oxidizing the gate stack for forming a protection enclosure having a protection layer along the sidewall.

7. The method as claimed in claim 6 wherein forming the charge trap layer having silicon includes forming a silicon rich nitride layer.

8. The method as claimed in claim 6 wherein slot plane antenna oxidizing the protection enclosure includes slot plane antenna oxidizing the sidewall of the top blocking oxide layer.

9. The method as claimed in claim 6 wherein forming the protection enclosure having the protection layer includes forming the protection layer comprised of oxide.

10. The method as claimed in claim 6 wherein the slot plane antenna oxidizing includes adjusting the oxidation of the polysilicon layer and the charge trap layer.

11. An integrated circuit system comprising:
a substrate;
a stack having a sidewall includes:
a charge trap layer over the substrate, and
a semi-conducting layer over the charge trap layer; and
a protection enclosure having a protection layer along the sidewall with the protection enclosure having the characteristic of being grown.

12. The system as claimed in claim 11 further comprising a protrusion of the charge trap layer from an encroachment characteristic of oxidation selectivity.

13. The system as claimed in claim 11 wherein the semi-conducting layer includes a rounded corner.

14. The system as claimed in claim 11 wherein the charge trap layer includes a rounded end.

15. The system as claimed in claim 11 further comprising an electronic system or a subsystem with the integrated circuit system.

16. The system as claimed in claim 11 wherein:
the substrate is a semiconductor substrate;
the stack is a gate stack having the sidewall including:
the charge trap layer, over the substrate, has silicon, and
the semi-conducting layer is a polysilicon layer over the charge trap layer; and
the protection enclosure has oxide having the protection layer along the sidewall with the protection enclosure having the characteristic of being grown.

17. The system as claimed in claim 16 wherein the charge trap layer having silicon includes a silicon rich nitride layer.

18. The system as claimed in claim 16 wherein the protection layer includes the protection layer along the sidewall of the charge trap layer.

19. The system as claimed in claim 16 further comprising a bottom tunneling oxide layer over the substrate and below the charge trap layer.

20. The system as claimed in claim 16 further comprising a top blocking oxide layer over the charge trap layer and below the semi-conducting layer.
